(19) United States
(12) Patent Application Publication
(10) Pub. No.: US 2026/0296879 A1
(43) Pub. Date: Oct. 1, 2026

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventors: RANGANATHAN NAGARAJAN, Singapore (SG); GUOFU ZHOU, Singapore (SG); BUAN FEI CHAN, Singapore (SG)

(73) Assignee: Vanguard International Semiconductor Corporation, Hsinchu (TW)

(21) Appl. No.: 19/093,232

(22) Filed: Mar. 27, 2025

(51) Int. Cl. B81B 7/00; B81C 1/00

(52) U.S. Cl. CPC B81B 7/0077; B81C 1/00333; B81B 2201/0235; B81B 2201/0242; B81B 2203/0315; B81B 2207/07; B81B 2207/097; B81C 2201/0132; B81C 2201/0133; B81C 2203/037

(57) ABSTRACT

A MEMS package includes a first substrate, a stopper, a device layer, and a release opening. The first substrate includes a cavity therein. The stopper is disposed in the cavity and integrated with the first substrate. The device layer includes a MEMS device and is bonded to the first substrate. The release opening penetrates the device layer, corresponds to the stopper, and is disposed in the MEMS device.

### BACKGROUND OF THE INVENTION

### 1. Field of the Invention

The present disclosure relates generally to micro-electro-mechanical system (MEMS) technology, and more particularly to MEMS packages that include a release opening corresponding to a Z-axis stopper, and fabrication methods thereof.

### 2. Description of the Prior Art

Micro-electro-mechanical system (MEMS) devices are microscopic devices that integrate mechanical and electrical components to sense physical quantities and/or to interact with the surrounding environment. MEMS devices, for example, accelerometers, gyroscopes, pressure sensors and microphones, have become widespread in many electronic products, such as tablet computers, automobiles, and smartphones. In the manufacturing of MEMS packages, a device wafer is usually bonded to a handle wafer. The handle wafer has a cavity, and a Z-axis bumper may be formed within the cavity. A sacrificial liner oxide is deposited on the bumper and in the cavity, and then removed by etching to release the bumper. However, etching the sacrificial liner oxide suffers from a loading effect, which reduces the production yield and the performance of MEMS packages.

### SUMMARY OF THE INVENTION

In view of this, the present disclosure provides a micro-electro-mechanical system (MEMS) package and a fabrication method thereof to overcome the aforementioned loading effect issue. The MEMS package includes a release opening penetrating a device layer and corresponding to a stopper within a cavity of a handle wafer. An etchant, used to release the stopper, is uniformly dispersed onto the stopper and into the cavity through the release opening, thereby overcoming the loading effect caused by the stopper in the cavity.

According to an embodiment of the present disclosure, a MEMS package is provided and includes a first substrate, a stopper, a device layer, and a release opening. The first substrate includes a cavity therein. The stopper is disposed in the cavity and integrated with the first substrate. The device layer includes a MEMS device and is bonded to the first substrate. The release opening penetrates the device layer, corresponds to the stopper, and is disposed in the MEMS device.

According to an embodiment of the present disclosure, a method of fabricating a micro-electro-mechanical system (MEMS) package is provided and includes the following steps. A first substrate is provided. A cavity and a stopper are formed by etching the first substrate. The stopper is formed within the cavity and integrated with the first substrate. A bonding material layer is formed to wrap around the first substrate, extending into the cavity and onto the stopper. A device layer is formed on the first substrate, to cover the cavity and the stopper, and is bonded to the first substrate through the bonding material layer. The device layer is patterned to form a MEMS device and a release opening. The release opening penetrates the device layer and corresponds to the stopper. In addition, a portion of the bonding material layer within the cavity and on the stopper is removed by etching to form a bonding layer, where an etchant flows through the release opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to some embodiments of the present disclosure.

FIG. 2 shows several schematic top views of a release opening, a stopper, and a portion of a MEMS device in a MEMS package according to some embodiments of the present disclosure.

FIG. 3, FIG. 4, FIG. 5, FIG. 6, FIG. 7, FIG. 8 and FIG. 9 are schematic cross-sectional views of some stages of a method for fabricating a MEMS package according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. For example, if the structure in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages that include a release opening disposed in a MEMS device, penetrating a device layer, and corresponding to a stopper. The stopper is disposed within a cavity of a handle wafer. The device layer is bonded to the handle wafer through a bonding layer that extends onto the stopper and into the cavity. The release opening allows an etchant to flow evenly across the stopper and into the cavity, thereby reducing the loading effect during etching of the bonding layer to release the stopper. Therefore, the production yield and performance of the MEMS packages are improved.

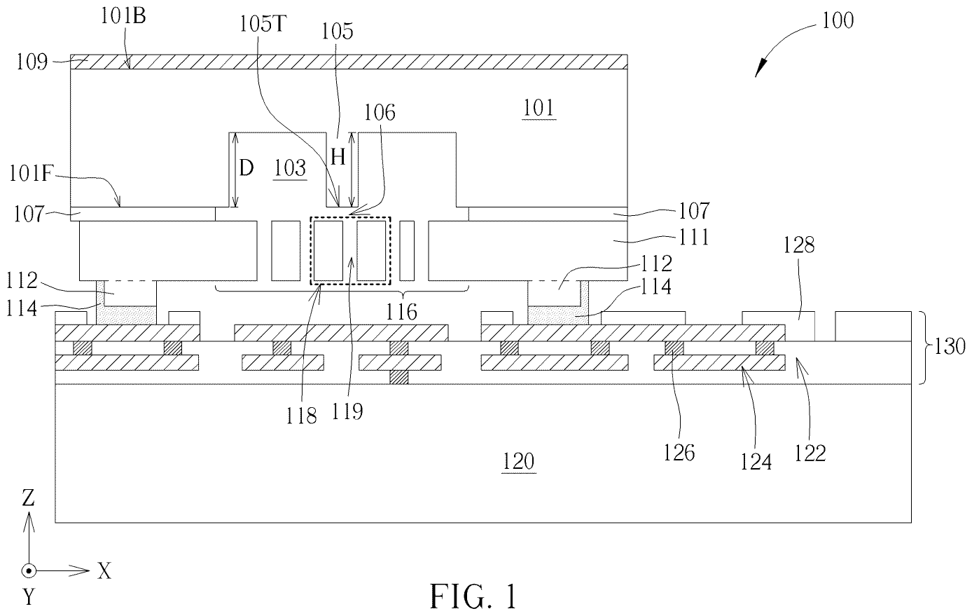

FIG. 1 is a schematic cross-sectional view of a MEMS package 100 according to some embodiments of the present disclosure. The MEMS package 100 includes a first substrate 101, a cavity 103, a stopper 105, a device layer 111, a release opening 119, a second substrate 120, and an interconnect layer 130. The first substrate 101 may be a silicon wafer, and has a front surface 101F and a back surface 101B on opposite sides. The first substrate 101 may be referred to as a handle wafer or a cap wafer. The cavity 103 is formed in the first substrate 101 and near the front surface 101F. The stopper 105 is disposed in the cavity 103 and is integrated with the first substrate 101. The stopper 105 has the same composition as that of the first substrate 101, for example, the stopper 105 may be a Z-axis silicon stopper. The composition of the first substrate 101 and the stopper 105 includes a single crystal semiconductor material, such as silicon, sapphire or other suitable semiconductor materials, for example elementary semiconductors as such as such Ge; compound semiconductors such as GaN, SiC, GaAs, GaP, InP, InAs, and/or InSb; alloy semiconductors such as SiGe, GaAsP, AlInAs, AlN, AlGaAs, GaInAs, GaInP, GaInAsP, or a combination thereof. In some embodiments, a surface 105T of the stopper 105 and the front surface 101F of the first substrate 101 are on the same level in the height (e.g. the Z-axis direction). The height H of the stopper 105 is substantially equal to the depth D of the cavity 103. In other embodiments, the height H of the stopper 105 may be less than the depth D of the cavity 103. The surface 105T of the stopper 105 and the front surface 101F of the first substrate 101 may not be at the same height. The surface 105T of the stopper 105 and the front surface 101F of the first substrate 101 both face to the device layer 111.

The device layer 111, including a MEMS device 116, is bonded to the first substrate 101 through a bonding layer 107, such as a silicon oxide layer (or referred to as liner oxide). After the stopper 105 is released by removing a sacrificial liner oxide, the bonding layer 107 is disposed between the first substrate 101 and the device layer 111, without extending into the cavity 103. Also, the bonding layer 107 does not extend onto the stopper 105. A gap 106 is formed between the stopper 105 and the device layer 111. In some embodiments, the height of the gap 106 (e.g. in the Z-axis direction) is substantially equal to the thickness of the bonding layer 107. In other embodiments, the height of the gap 106 in the Z-axis direction may be greater than the thickness of the bonding layer 107.

The device layer 111 includes features such as trenches, cantilever beams, membranes, and proof masses 118 to construct the MEMS device 116, such as an accelerometer, a gyroscope, an inertial measurement unit (IMU) device, or other MEMS devices. The composition of the device layer 111 includes doped or undoped silicon, doped or undoped polysilicon, other or doped or undoped suitable semiconductor materials. The proof mass 118 may function as a movable proof mass, while the MEMS device 116 is an accelerometer or a gyroscope. During operation of the MEMS device 116, the proof mass 118 may be displaced from its original place by an external force applied to the MEMS device 116. The stopper 105 damps the Z-axis movement of the proof mass 118, thus improving the performance of the MEMS device 116. The proof mass 118 is located directly beneath the stopper 105, thereby preventing breakage of the MEMS device 116 due to vibration or shock to the MEMS device layer 111.

In some embodiments, the release opening 119 is disposed in the proof mass 118 of the MEMS device 116. The release opening 119 penetrates the device layer 111 and aligns with the stopper 105. During the MEMS package 100 manufacturing, the sacrificial liner oxide of the bonding layer 107 within the cavity 103 and on the stopper 105 is removed by etching, thereby releasing the stopper 105 and forming the gap 106. The etchant, used to remove the sacrificial liner oxide, is uniformly dispersed onto the stopper 105 and into the cavity 103 through the release opening 119, thereby avoiding or reducing the loading effect during this etching process. Thereafter, in the MEMS package 100, the release opening 119, the gap 106, and the cavity 103 are interconnected.

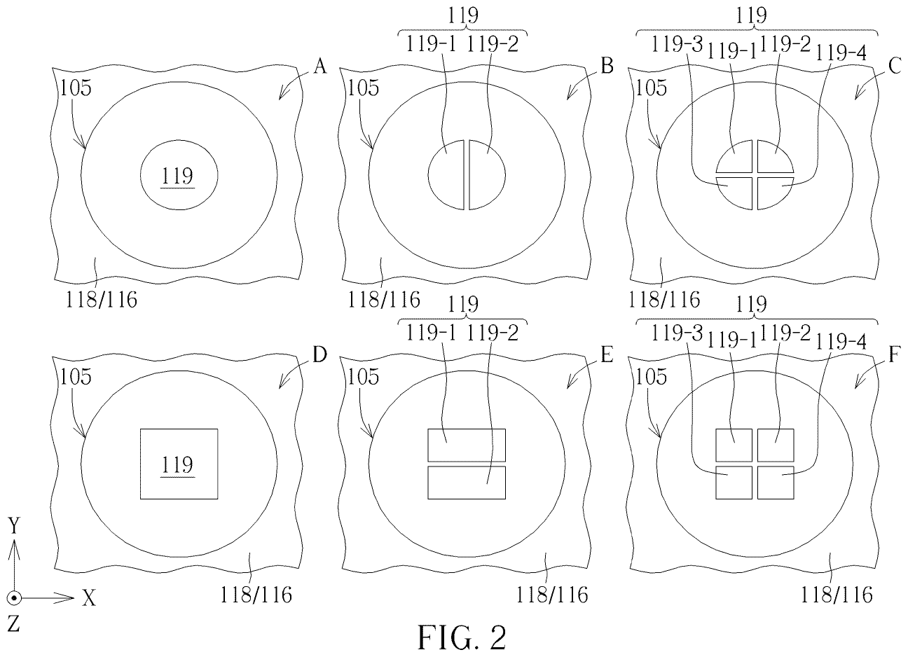

FIG. 2 shows several schematic top views of the release opening 119, the stopper 105, and a portion of the MEMS device 116 such as the proof mass 118 in the MEMS package 100 according to some embodiments of the present disclosure. As shown in FIG. 2, in the vertical projection direction (e.g., the XY-plane), the release opening 119 overlaps and aligns with the stopper 105. Moreover, the release opening 119 is within the boundary of the stopper 105. The release opening 119 is disposed in and penetrates the proof mass 118.

In some embodiments, as shown in the top views A, B and C of FIG. 2, the outline of the release opening 119 may be a circle. In some other embodiments, as shown in the top views D, E and F of FIG. 2, the outline of the release opening 119 may be a square. Furthermore, as shown in the top views B, C, E and F, the release opening 119 includes multiple sub-openings separated from each other. In some embodiments, the release opening 119 may include two sub-openings 119-1 and 119-2. In other embodiments, the release opening 119 may include four sub-openings 119-1, 119-2, 119-3 and 119-4. These sub-openings are evenly distributed within the outline of the release opening 119, thereby facilitating the uniform dispersion of the etchant onto the stopper 105 and into the cavity 103. It is beneficial to avoid or reduce the loading effect during the etching process of removing the sacrificial liner oxide in the cavity 103 and on the stopper 105.

In some embodiments, these sub-openings 119-1, 119-2, 119-3 and 119-4 are separated by a space, for example, about 2 μm to about 5 μm, but not limited thereto. The diameter, the width, or the length of the release opening 119 may be about 2 μm to about 20 μm, but not limited thereto. The dimension of the release opening 119 and the space between the sub-openings 119-1, 119-2, 119-3 and 119-4 may be adjusted based on the dimensions of the proof mass 118 and the stopper 105. For example, the area of the release opening 119 may be about 10% to 75% of the area of the stopper 105, but not limited thereto. The area of the release opening 119 may be about 58 to 15% of the area of the proof mass 118, but not limited thereto. In addition, the dimension of the release opening 119 and the space between the sub-openings may be adjusted according to the parameters of the etching process and the etchant types to remove the sacrificial liner oxide. The outline of the release opening 119 is not limited to circles and squares, and may include other shapes such as polygons, ellipses, honeycomb-shaped, etc.

Referring to FIG. 1 again, the MEMS package 100 includes a stand-off structure 112 integrated with the device layer 111. The stand-off structure 112 is a bond ring, surrounding the MEMS device 116 and protruding toward the interconnect layer 130 and the second substrate 120. The stand-off structure 112 has the same composition as the MEMS device layer 111. In some embodiments, the composition of the MEMS device layer 111 and the stand-off structure 112 may be doped silicon or doped polysilicon. The device layer 111 is bonded to the interconnect layer 130 through the stand-off structure 112 and a bonding material 114. In some embodiments, the bonding material 114 may be a eutectic bonding material such as a eutectic alloy of aluminum (Al) and germanium (Ge), i.e., Al—Ge.

The interconnect layer 130 is disposed on the second substrate 120. In some embodiments, the second substrate 120 may be a silicon wafer including CMOS transistors or other elements formed therein. The interconnect layer 130 and the second substrate 120 together may be referred to as a CMOS/interconnect wafer. The interconnect layer 130 includes multiple metal layers 124, multiple dielectric layers 122, multiple conductive vias 126, and a passivation layer 128. These metal layers 124 include a top metal layer, several intermediate metal layers, and a bottom metal layer. The top metal layer is, for example, an aluminum (Al) layer, and provides a seal ring bonded to the stand-off structure 112. The seal ring of the top metal layer is exposed by the passivation layer 128 and is in direct contact with the bonding material 114. These dielectric layers 122 include several inter-metal dielectric (IMD) layers and an interlayer dielectric (ILD) layer. These dielectric layers 122 are, for example, silicon oxide layers. Some of the conductive vias 126 are disposed in the IMD layers to electrically connect any two of these metal layers 124. Some of the conductive vias 126 are disposed in the ILD layer to electrically connect the bottom metal layer to the CMOS transistors or other elements in the second substrate 120. The interconnect layer 130 is thereby electrically coupled to the CMOS transistors or other elements in the second substrate 120.

Furthermore, a metal layer 109 is disposed on the back surface 101B of the first substrate 101. The metal layer 109 is, for example, an aluminum (Al) layer, provided for radio frequency (RF) shielding and/or grounding. The top metal layer of the interconnect layer 130 further provides a bond pad electrically connected to the metal layer 109. This bond pad is exposed by the passivation layer 128 and is configured to be connected to a ground voltage.

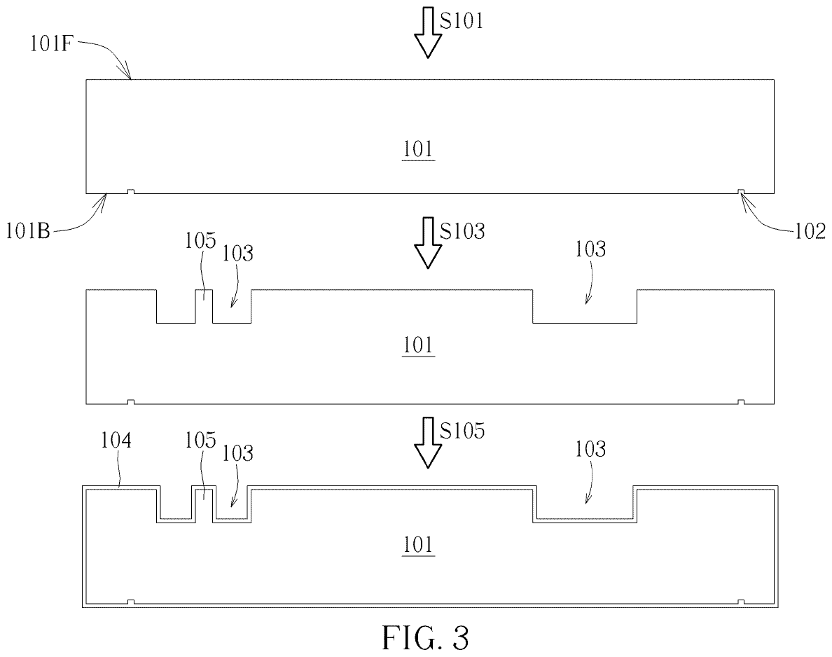

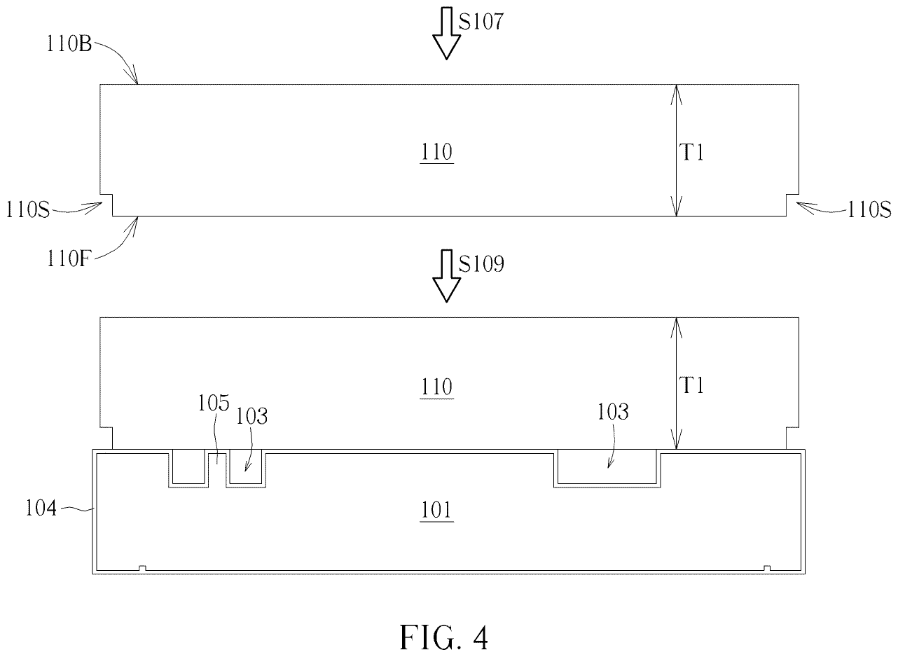

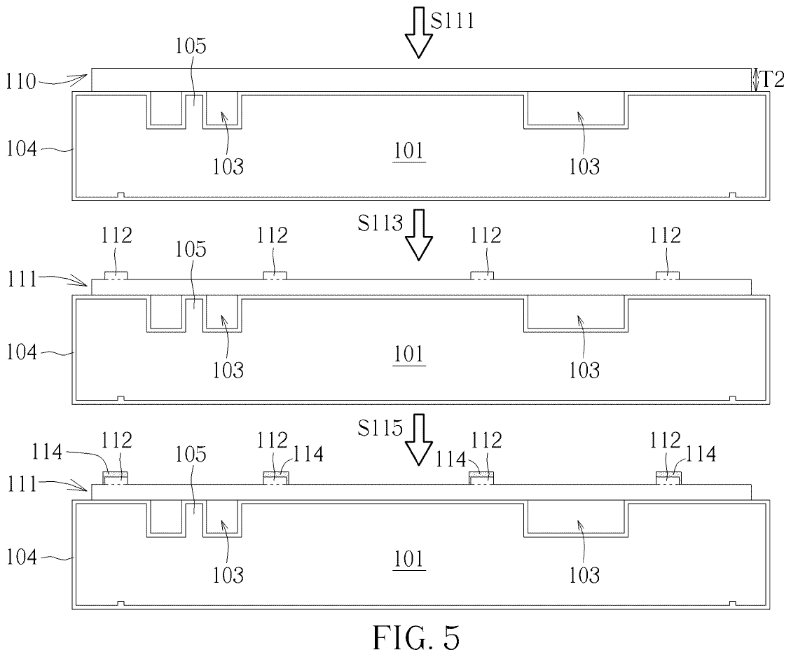

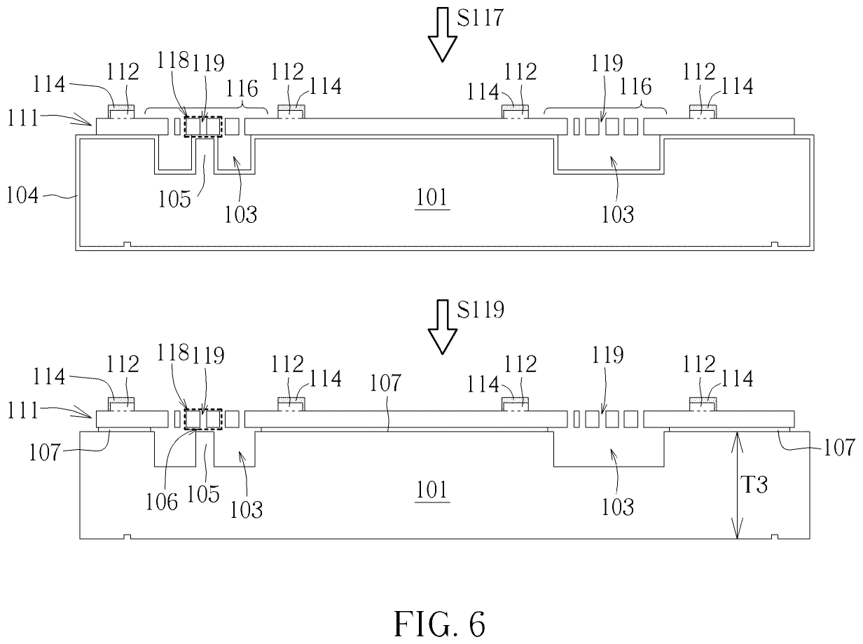

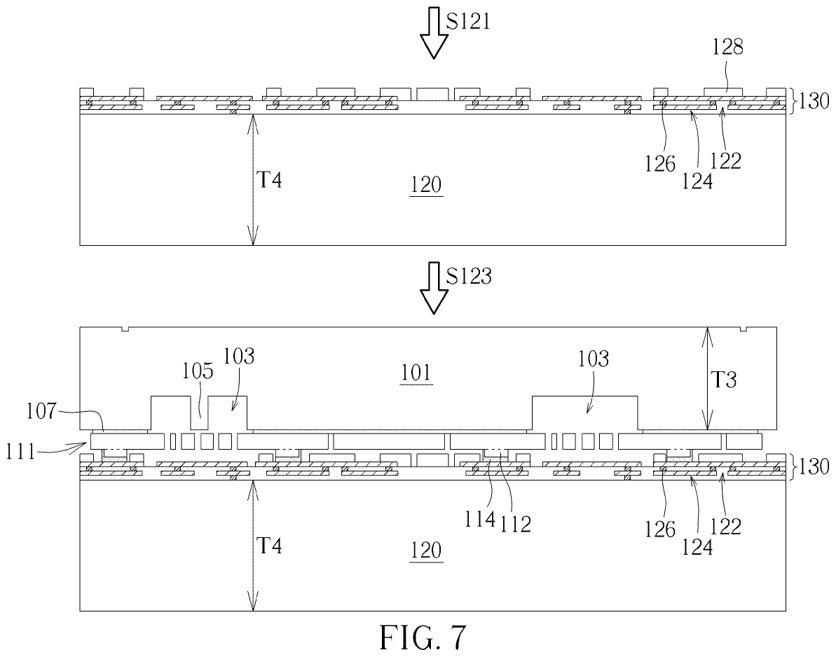

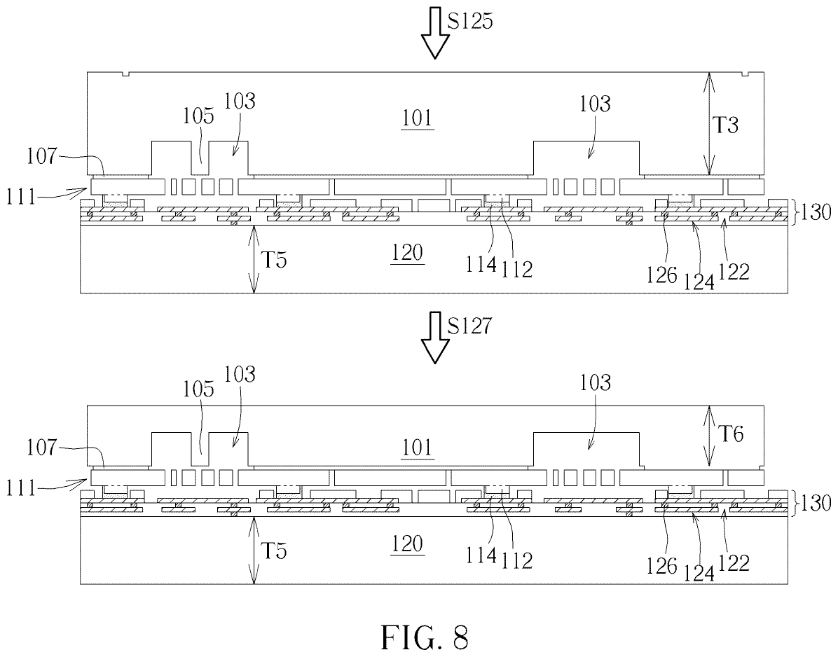

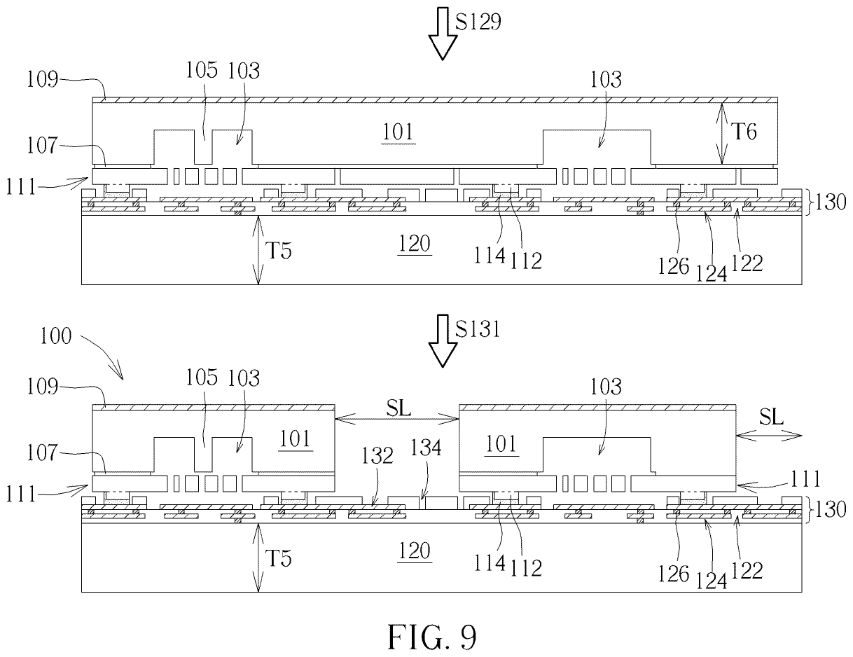

FIG. 3, FIG. 4, FIG. 5, FIG. 6, FIG. 7, FIG. 8 and FIG. 9 are schematic cross-sectional views of some stages of a method for fabricating a MEMS package 100 according to some embodiments of the present disclosure. Referring to FIG. 3, in step S101, a first substrate 101 such as a silicon wafer is provided as a handle wafer or a cap wafer. The first substrate 101 is polished on both the front surface 101F and the back surface 101B. Multiple alignment marks 102 are formed on the back surface 101B of the first substrate 101 by patterning and etching. Next, in step S103, multiple cavities 103 and multiple stoppers 105 are simultaneously formed at the front side 101F of the first substrate 101 by using a patterned hard mask (not shown) and etching. In some embodiments, these stoppers 105 are formed within some of the cavities 103 and integrated with the first substrate 101. The height H of the stopper 105 is substantially equal to the depth D of the cavity 103, for example, about 20 μm. Some of the cavities 103 do not have the stopper 105 formed therein. Then, in step S105, a bonding material layer 104 is conformally formed on the first substrate 101, extending into the cavities 103 and onto the stoppers 105 to wrap around the first substrate 101. The bonding material layer 104 is, for example, a silicon oxide layer (e.g., liner oxide), and may be formed by thermal oxidation. The thickness of the bonding material layer 104 may be about 1.1 μm.

Next, referring to FIG. 4, in step S107, a device wafer 110 such as a silicon wafer is provided and polished on its front side 110F. The device wafer 110 may be heavily doped with boron to achieve a resistivity of about 0.008 ohm·cm to about 0.02 ohm·cm. Then, the device wafer 110 is trimmed at its edges 110S on the front side 110F. Afterwards, in step S109, the front side 110F of the device wafer 110 is bonded to the first substrate 101 through the bonding material layer 104 by fusion bonding (oxide to silicon). The device wafer 110 covers the cavities 103 and the stoppers 105. In step S107 and step S109, the device wafer 110 has a thickness T1.

Then, referring to FIG. 5, in step S111, the device wafer 110 is thinned by grinding on its back side to achieve a thickness T2 that is less than the thickness T1. Moreover, a chemical-mechanical polish (CMP) process is performed on the back side of the thinned device wafer 110. Next, in step S113, the thinned device wafer 110 is patterned by photolithography and etching processes to form multiple stand-off structures 112 integrated with a device layer 111. The stand-off structures 112 protrude from a surface of the device layer 111. Thereafter, in step S115, a bonding material 114 is formed on the stand-off structures 112 by deposition and patterning process. In some embodiments, the bonding material 114 may be germanium (Ge) for eutectic bonding, but is not limited thereto.

Next, referring to FIG. 6, in step S117, the device layer 111 is patterned by photolithography and etching processes to simultaneously form multiple MEMS devices 116 and multiple release openings 119. These MEMS devices 116 and release openings 119 are formed by using the same patterned mask and the same etching process. In some embodiments, the MEMS devices 116 may be gyroscopes, accelerometers, an inertial measurement unit (IMU) device, and/or other MEMS devices. Each of the MEMS devices 116 is surrounded by the stand-off structure 112 and located directly above the cavity 103. Moreover, at least one MEMS device 116 may include a proof mass 118 disposed directly above the stopper 105. At least one release opening 119 is formed in the proof mass 118, penetrating the device layer 111, and corresponding to the stopper 105. The release opening 119 may also be formed in another MEMS device 116, penetrating the device layer 111, and corresponding to the cavity 103 without the stopper 105 therein.

The release openings 119 formed in the MEMS devices 116 may have one of the top views A, B, C, D, E, and F, as shown in FIG. 2, or a combination thereof. For example, a release opening 119 in a MEMS device 116 may have one circular or square opening, or multiple sub-openings. These sub-openings are separated and are evenly distributed within the outline of the release opening 119. In one MEMS device 116, the release opening 119 exposes a portion of the bonding material layer 104 on the stopper 105. In another MEMS device 116, the release opening 119 provides an additional passage to connect to the cavity 103.

Afterwards, still referring to FIG. 6, in step S119, some portions of the bonding material layer 104 within the cavities 103 and on the stoppers 105 are removed by a dry or wet etching process. An etchant used in the dry etching process is, for example, a hydrofluoric acid vapor. An etchant used in the wet etching process is, for example, a hydrofluoric acid solution. During this etching process, the etchant flows through the release openings 119 onto the stoppers 105 and into the cavities 103. The etchant is uniformly dispersed onto the stopper 105 and into the cavities 103 through the release openings 119 to remove some portions of the bonding material layer 104, thereby reducing the loading effect in this etching process and improving the production yield of MEMS packages.

After the portions of the bonding material layer 104 within the cavities 103 and on the stoppers 105 are removed, a gap 106 is formed between the stoppers 105 and the device layer 111 to release the stoppers 105. In some embodiments, the height of the gap 106 (e.g., in the Z-axis direction) is substantially equal to the thickness of the bonding material layer 104, for example, about 1.1 μm. Moreover, after step S119, the portions of the bonding material layer 104 on the sidewalls 101S and the back surface 101B of the first substrate 101 are also removed by this etching process. Thereafter, a bonding layer 107 is formed between the device layer 111 and the front surface 101F of the first substrate 101. In step S119, the first substrate 101 has a thickness T3.

Next, referring to FIG. 7, in step S121, a second substrate 120 such as a silicon wafer is provided with multiple CMOS transistors formed therein, and the second substrate 120 may be referred to as a CMOS wafer. Then, an interconnect layer 130 is formed on the front side of the second substrate 120. The details of the interconnect layer 130 may refer to the aforementioned descriptions of the MEMS package 100 in FIG. 1, and not repeated herein. In step S121, the second substrate 120 has a thickness T4.

Afterwards, still referring to FIG. 7, in step S123, the structure in step S119 of FIG. 6 is inverted, and the device layer 111 is bonded to the interconnect layer 130 through the stand-off structure 112 and the bonding material 114. The stand-off structure 112 protrudes toward the interconnect layer 130 and the second substrate 120. In some embodiments, the device layer 111 is bonded to the interconnect layer 130 by eutectic bonding, and the bonding material 114 may be Al—Ge alloy.

Next, referring to FIG. 8, in step 125, the second substrate 120 is thinned by grinding on its back side to achieve a thickness T5 that is less than the thickness T4 in step S123. Then, the edges of the first substrate 101 are trimmed to be smaller than the second substrate 120 and the interconnect layer 130. The first substrate 101 still has the thickness T3 in step 125. Then, in step S127, the first substrate 101 is thinned by grinding on its back surface to achieve a thickness T6 that is less than the thickness T3.

Next, referring to FIG. 9, in step 129, a metal layer 109 such as an Al layer is deposited on the back surface of the first substrate 101. The thickness of the metal layer 109 is, for example about 0.8 μm. Then, in step S131, portions of the metal layer 109, the first substrate 101 and the device layer 111 at scribe lines SL are cut through by tab dicing with a saw blade, thereby exposing a bond pad 132 in the top metal layer and a pre-cut line 134 in the passivation layer of the interconnect layer 130. Thereafter, the interconnect layer 130 and the second substrate 120 are diced along the pre-cut line 134 to complete the MEMS package 100 of FIG. 1, and another MEMS package without the stopper in the cavity.

According to embodiments of the present disclosure, the MEMS packages include a release opening disposed in the MEMS device, penetrating the device layer, and corresponding to the stopper within the cavity of the first substrate. The release opening allows the etchant, removing some portions of the bonding material layer, to flow evenly across the stopper and into the cavity, thereby reducing the loading effect during the etching process. Therefore, the production yield and performance of the MEMS packages are improved.

Moreover, the release opening and the MEMS device are simultaneously formed using the same patterned mask and etching process, thereby saving process steps and manufacturing costs for the MEMS packages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a first substrate, including a cavity therein;
a stopper, disposed in the cavity and integrated with the first substrate;
a device layer, comprising a MEMS device and bonded to the first substrate; and
a release opening, penetrating the device layer, corresponding to the stopper, and disposed in the MEMS device.

2. The MEMS package of claim 1, wherein in a vertical projection direction, the release opening overlaps the stopper.

3. The MEMS package of claim 1, wherein the release opening comprises a plurality of sub-openings separated from each other.

4. The MEMS package of claim 3, wherein in a top view, an outline of the release opening comprises a circle or a square, and the plurality of sub-openings are evenly distributed within the outline of the release opening.

5. The MEMS package of claim 1, wherein in a vertical projection direction, the release opening is within a boundary of the stopper.

6. The MEMS package of claim 1, further comprising a bonding layer disposed between the first substrate and the device layer, wherein the bonding layer is not extended into the cavity and onto the stopper.

7. The MEMS package of claim 6, wherein a gap is between the stopper and the device layer, and a height of the gap is equal to a thickness of the bonding layer.

8. The MEMS package of claim 7, wherein the release opening, the gap, and the cavity are interconnected.

9. The MEMS package of claim 1, wherein the first substrate has a front surface and a back surface, the stopper has a surface, the front surface of the first substrate and the surface of the stopper both face to the device layer and are on the same level in a height.

10. The MEMS package of claim 1, wherein the MEMS device comprises a proof mass, and the release opening is disposed in the proof mass.

11. The MEMS package of claim 1, further comprising:
a second substrate;
an interconnect layer, disposed on the second substrate; and
a stand-off structure, integrated with the device layer, surrounding the MEMS device, protruding toward the second substrate, and bonded to the interconnect layer.

12. The MEMS package of claim 1, wherein the MEMS device comprises an accelerometer, a gyroscope, or an inertial measurement unit (IMU).

13. A method of fabricating a micro-electro-mechanical system (MEMS) package, comprising:
providing a first substrate;
forming a cavity and a stopper by etching the first substrate, wherein the stopper is formed within the cavity and integrated with the first substrate;
forming a bonding material layer to wrap around the first substrate, extending into the cavity and onto the stopper;
forming a device layer on the first substrate to cover the cavity and the stopper, wherein the device layer is bonded to the first substrate through the bonding material layer;
patterning the device layer to form a MEMS device and a release opening, wherein the release opening penetrates the device layer and corresponds to the stopper; and
removing a portion of the bonding material layer within the cavity and on the stopper by etching to form a bonding layer, wherein an etchant flows through the release opening.

14. The method of claim 13, wherein removing the portion of the bonding material layer comprises a dry etching or a wet etching process.

15. The method of claim 13, wherein the etchant comprises a hydrofluoric acid vapor or a hydrofluoric acid solution.

16. The method of claim 13, wherein the MEMS device comprises a proof mass, and the release opening is formed in the proof mass.

17. The method of claim 13, wherein forming the release opening comprises forming a plurality of sub-openings separated from each other and evenly distributed within an outline of the release opening.

18. The method of claim 13, wherein the MEMS device and the release opening are simultaneously formed in the device layer by the same etching process, and the release opening exposes the bonding material layer on the stopper before removing the portion of the bonding material layer within the cavity and on the stopper.

19. The method of claim 13, wherein after the portion of the bonding material layer within the cavity and on the stopper is removed, a gap is formed between the stopper and the device layer, and a height of the gap is equal to a thickness of the bonding layer.

20. The method of claim 13, further comprising:
providing a second substrate;
forming an interconnect layer on the second substrate;
forming a stand-off structure on the device layer before patterning the device layer to form the MEMS device and the release opening, wherein the stand-off structure protrudes toward the second substrate and surrounds the MEMS device; and
bonding the device layer to the interconnect layer through the stand-off structure by eutectic bonding.
